(19) United States
(12) Patent Application Publication
(10) Pub. No.: US 2026/0136576 A1
(43) Pub. Date: May 14, 2026

(54) SEMICONDUCTOR DEVICE WITH GATE PROTECTIVE LAYER

(71) Applicant: TAIWAN SEMICONDUCTOR MANUFACTURING COMPANY, LTD., Hsinchu (TW)

(72) Inventors: Chun Yi CHOU, Hsinchu City (TW); Guan-Lin CHEN, Hsinchu County (TW); Kuo-Cheng CHIANG, Hsinchu County (TW); Chih-Hao WANG, Hsinchu County (TW)

(73) Assignee: TAIWAN SEMICONDUCTOR MANUFACTURING COMPANY, LTD., Hsinchu (TW)

(21) Appl. No.: 18/948,113

(22) Filed: Nov. 14, 2024

(51) Int. Cl. H01L 29/66; H01L 21/28; H01L 29/06; H01L 29/423; H01L 29/49; H01L 29/775; H01L 29/786

(52) U.S. Cl. CPC H10D 30/014; H10D 30/43; H10D 30/6735; H10D 30/6739; H10D 30/6757; H10D 62/121; H10D 64/01318; H10D 64/017; H10D 64/018

(57) ABSTRACT

A method of forming a semiconductor device comprises the following steps. A multi-layer stack is formed over a substrate. The multi-layer stack comprises alternately stacked first semiconductor layers and second semiconductor layers. A dielectric protective layer is formed over the multi-layer stack. Gate spacers are formed over the dielectric protective layer. A first portion of the dielectric protective layer is removed from a top surface of the multi-layer stack, while leaving second portions of the dielectric protective layer under the gate spacer. The first semiconductor layers are replaced with a metal gate stack. A gate contact is formed over the metal gate stack.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanosheet field-effect transistor (NSFET) device in a three-dimensional view, in accordance with some embodiments.

FIG. 2 is a cross-sectional view of the NSFET device at subsequent stages of manufacturing, in accordance with an embodiment.

FIGS. 3, 4 and 5A are cross-sectional views along cross-section C-C′ in FIG. 1.

FIGS. 5B, 17C, 18C, 21B and 22B are cross-sectional views along cross-section A-A′ in FIG. 1.

FIGS. 5C, 6, 7, 8, 9, 10, 11, 12, 13, 14, 15, 16, 17A, 18A, 19, 20, 21A and 22A are cross-sectional views along cross-section B-B′ in FIG. 1.

FIG. 17B is an enlarged view in FIG. 17A in accordance with some embodiments.

FIG. 18B is an enlarged view in FIG. 18A in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise specified, the same or similar reference numerals in different figures refer to the same or similar component formed by a same or similar process using a same or similar material(s).

In gate protect top (GPT) scheme, a gate protective layer may be formed on a top of an active area which is also referred to herein as an oxide definition (OD) area or pattern. During a subsequent gate contact formation process, an additional etch process is performed to break through the gate protective layer and a gate dielectric layer to connect to the underlying fill metal. However, this etching process may inadvertently remove some of the fill metal and oxidize the work function metal, resulting in high contact resistance.

To address the issue of high contact resistance issue in the gate protect top scheme, it is essential to ensure sufficient fill metal remains before the gate contact formation process. However, increasing the thickness of the fill metal within the limited sheet-to-sheet space can reduce the available space for the work function metal.

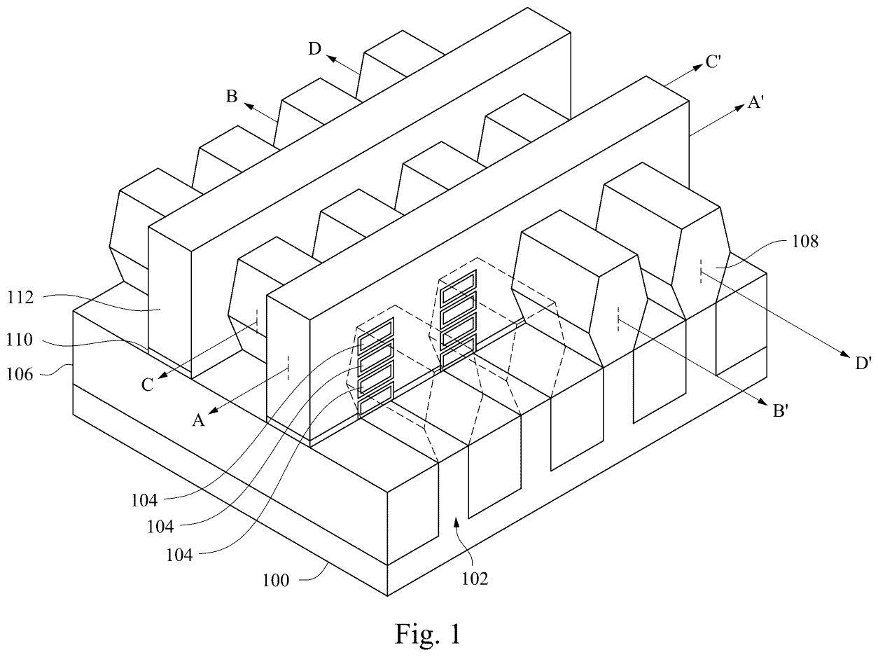

Embodiments of the present disclosure provide a solution where the gate protective layer is removed prior to forming a metal gate stack. This approach creates more space for the metal gate stack formation. With the gate protective layer removed and the metal gate stack having increased thickness, the margin for gate contact etching process without excessively etching the fill metal of the metal gate stack is improved. Consequently, the gate contact can interface with the fill material, thereby reducing contact resistance. The various aspects of the present disclosure will be discussed below in greater detail with reference to FIGS. 1-22B.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

FIG. 1 illustrates an example of a nanosheet field-effect transistor (NSFET) device in a three-dimensional view, in accordance with some embodiments. The NSFET device comprises semiconductor fins 102 (also referred to as fins) protruding above a substrate 100. A gate electrode (e.g., a metal gate) 112 is disposed over the fins 102, and source/drain regions 108 are formed on opposing sides of the gate electrode 112. A plurality of nanosheets 104 are formed over the fins 102 and between source/drain regions 108. Isolation regions 106 are formed on opposing sides of the fins 102. A gate dielectric layer 110 is formed around the nanosheets 104. Gate electrodes 112 are over and around the gate dielectric layer 110.

FIG. 1 further illustrates reference cross-sections that are used in later figures. Cross-section A-A′ is along a longitudinal axis of a gate electrode and in a direction, for example, perpendicular to the direction of current flow between the source/drain regions of an NSFET device. Cross-sections B-B′ and D-D′ are perpendicular to cross-section A-A′ and are along a longitudinal axis of a fin and in a direction of, for example, a current flow between the source/drain regions of the NSFET device. Cross-section C-C′ is parallel to cross-section A-A′ and extends through epitaxial source/drain regions of the NSFET device. Subsequent figures refer to these reference cross-sections for clarity.

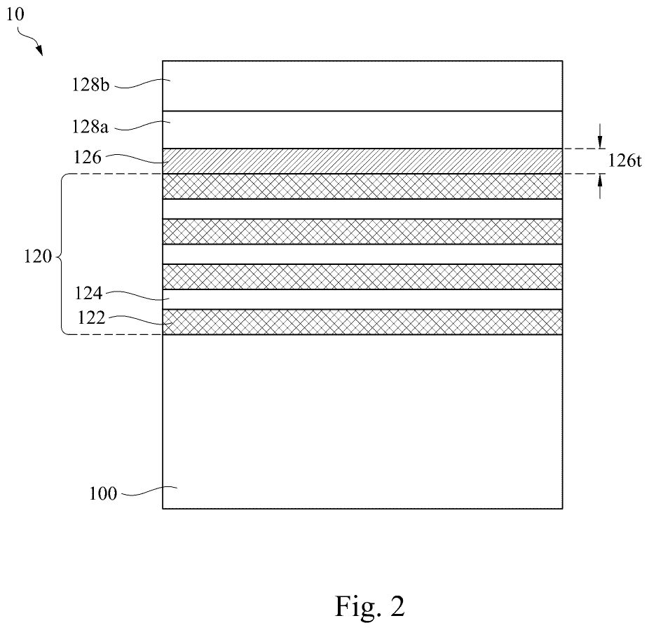

FIG. 2 is a cross-sectional view of the NSFET device 10 at subsequent stages of manufacturing, in accordance with an embodiment. In FIG. 2, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 100 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the NSFET device 10 can be for forming n-type devices, such as n-channel metal-oxide-semiconductor (NMOS) transistors, e.g., n-type GAA-FETs, or can be for forming p-type devices, such as p-channel metal-oxide-semiconductor (PMOS) transistors, e.g., p-type GAA-FETs.

A multi-layer stack 120 can be formed on the substrate 100. A gate protective layer (or gate protective material) 126 can be formed on the multi-layer stack 120. The multi-layer stack 120 includes alternating layers of a first semiconductor material 122 and a second semiconductor material 124. In FIG. 2, layers formed by the first semiconductor material 122 are labeled as 122, and layers formed by the second semiconductor material 124 are labeled as 124. The number of layers formed by the first and second semiconductor materials 122 and 124 illustrated in FIG. 2 are merely non-limiting examples. Other numbers of layers are also possible and are fully intended to be included within the scope of the present disclosure. In some embodiments, the gate protective layer can be a dielectric layer including such as SiCN, SiOCN, the like, or a combination thereof. In some embodiments, the gate protective layer 126 can include a thickness 126t in a range from about 3 nm to about 15 nm.

In some embodiments, the first semiconductor material 122 is an epitaxial material suitable for forming channel regions of, e.g., p-type FETs, such as silicon germanium (SiₓGe₁₋ₓ, where x can be in the range of 0 to 1). The second semiconductor material 124 is a silicon material being an epitaxial material suitable for forming channel regions of, e.g., n-type FETs. The multi-layer stacks 120 (may also be referred to as an epitaxial material stack) will be patterned to form channel regions of an NSFET in subsequent processing. In particular, the multi-layer stack 120 will be patterned to form horizontal nanosheets, with the channel regions of the resulting NSFET including multiple horizontal nanosheets.

The multi-layer stack 120 may be formed by an epitaxial growth process, which may be performed in a growth chamber. During the epitaxial growth process, the growth chamber is cyclically exposed to a first set of precursors for selectively growing the first semiconductor material 122, and then exposed to a second set of precursors for selectively growing the second semiconductor material 124, in some embodiments. The first set of precursors includes precursors for the first semiconductor material (e.g., silicon germanium), and the second set of precursors includes precursors for the second semiconductor material. In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 122; and (2) disabling the flow of the germanium precursor to the growth chamber when growing the second semiconductor material 124. The cyclical exposure may be repeated until a target quantity of layers is formed. The protective layer can be formed by a suitable deposition process, such as chemical vapor deposition (CVD), atomic layer deposition (ALD), physical vapor deposition (PVD), or the like.

In some embodiments, one or more hard mask layers may be formed on the gate protective layer 126. In some embodiments, the hard mask layers include a first mask layer 128a and a second mask layer 128b. The first mask layer 128a is a pad oxide layer made of a silicon oxide, which can be formed by a thermal oxidation. The second mask layer 128b is made of a silicon nitride (SiN), which is formed by CVD, including low pressure CVD (LPCVD) and plasma enhanced CVD (PECVD), PVD, ALD, or other suitable process.

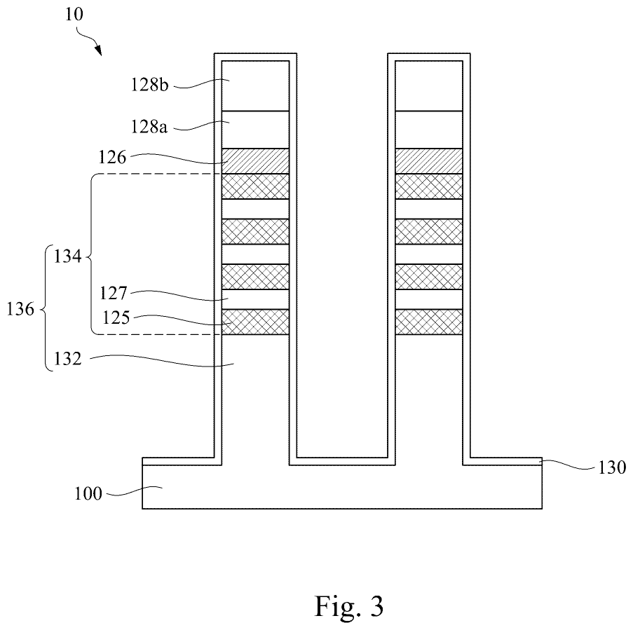

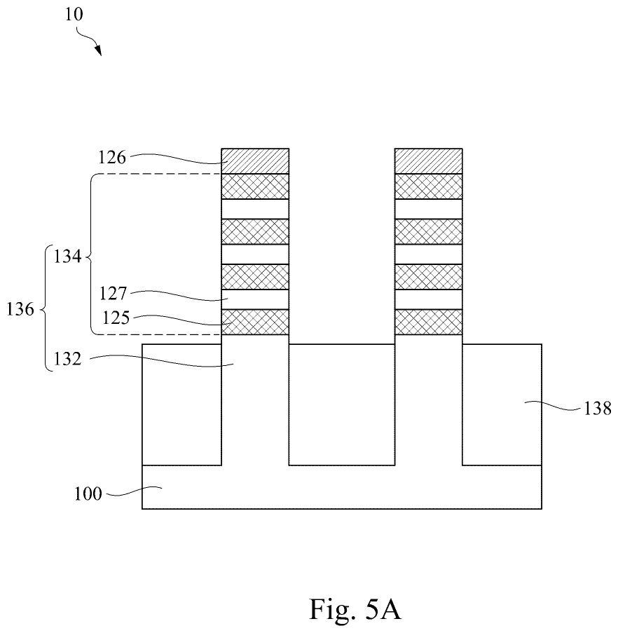

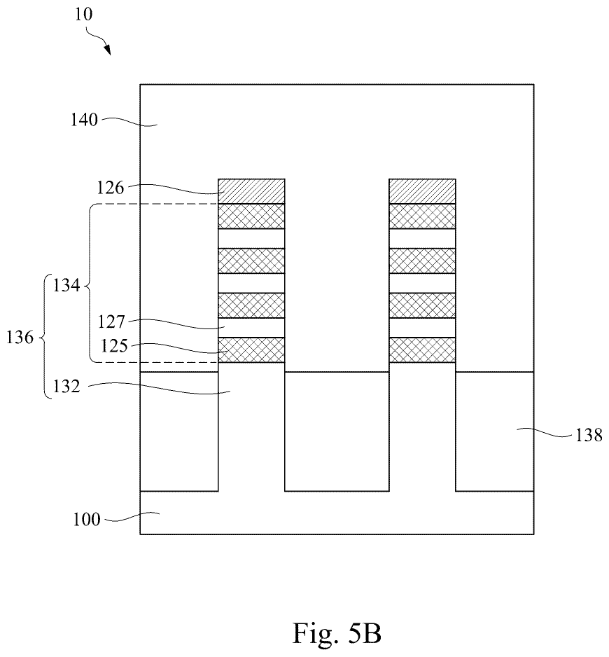

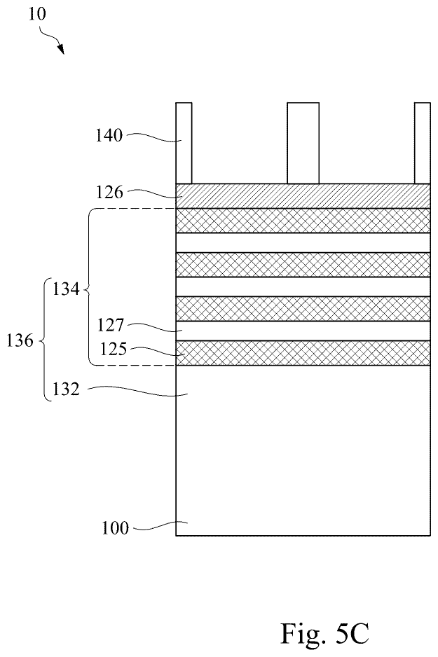

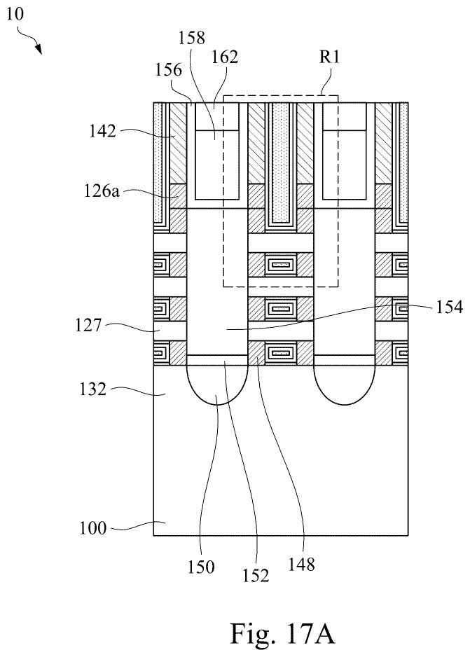

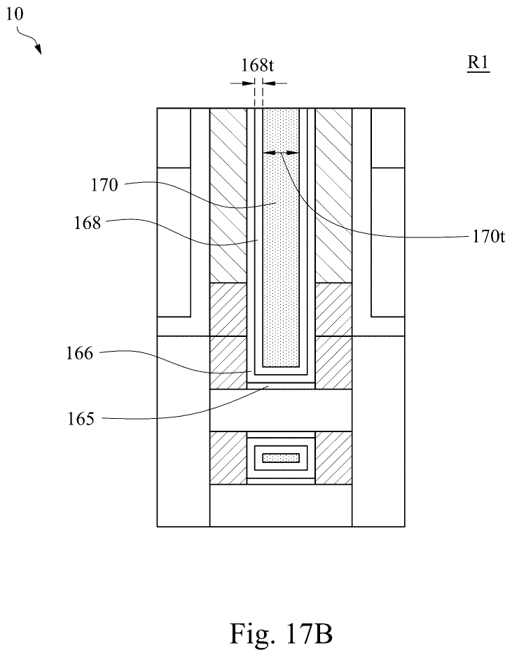

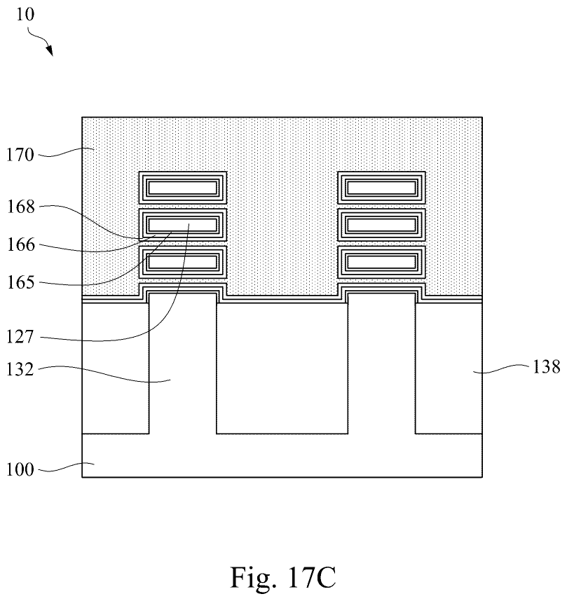

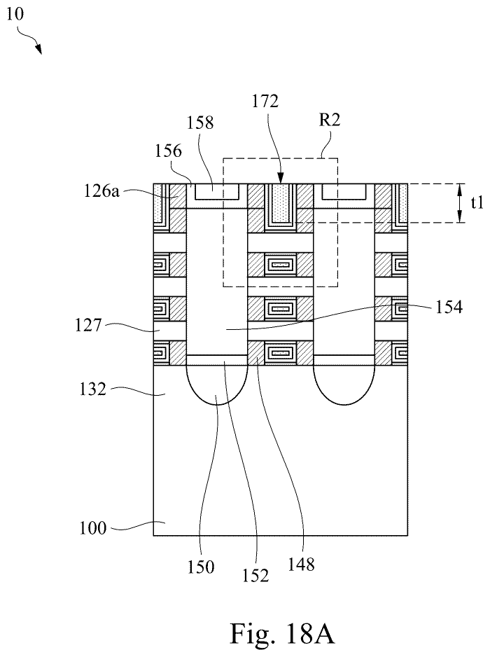

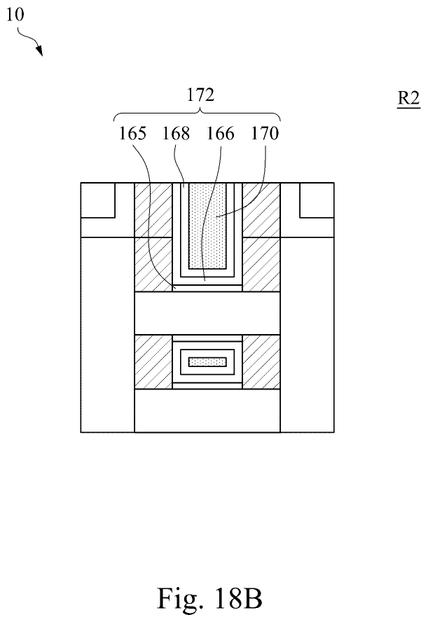

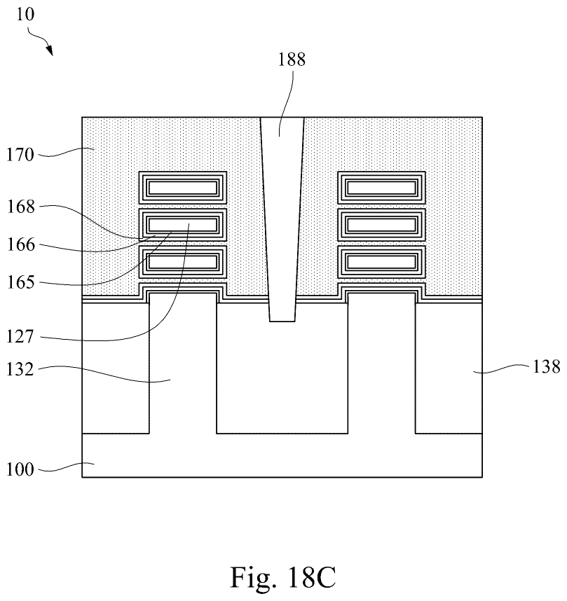

FIGS. 3-22B are cross-sectional views of the NSFET device 10 at subsequent stages of manufacturing, in accordance with an embodiment. FIGS. 5B, 17C and 22B are cross-sectional views along cross-section A-A′ in FIG. 1. FIGS. 5C, 6, 7, 8, 9, 10, 11, 12, 13, 14, 15, 16, 17A, 18A, 19, 20, 21A and 22A are cross-sectional views along cross-section B-B′ in FIG. 1. FIGS. 3, 4 and 5A are cross-sectional views along cross-section C-C′ in FIG. 1. FIG. 17B is an enlarged view in FIG. 17A in accordance with some embodiments. FIG. 18B is an enlarged view in FIG. 18A in accordance with some embodiments. Although two fins and three gate structures are illustrated in the figures as a non-limiting example, it should be appreciated that other numbers of fins and other numbers of gate structures may also be formed.

In FIG. 3, the first mask layer 128a and the second mask layer 128b are patterned into a mask pattern by using patterning operations including photolithography and etching. In FIG. 3, fin structures 136 are formed protruding above the substrate 100 using the patterned first mask layer 128a and the patterned second mask layer 128b. The fin structures 136 each include a semiconductor fin 132 and a nanostructure 134 overlying the semiconductor fin 132. The nanostructure 134 and the semiconductor fin 132 may be formed by etching trenches in the multi-layer stack 120 and the substrate 100, respectively. The etching may be anisotropic. Forming the nanostructures 134 by etching the multi-layer stack 120 may further define first nanostructures 125 from the first semiconductor layers 122 and define second nanostructures 127 from the second semiconductor layers 124. The first nanostructures 125 and the second nanostructures 127 may further be collectively referred to as nanostructures 134.

In FIG. 3, two fin structures 136 are arranged in the Y direction. But the number of the fin structures 136 is not limited to two, and may be as small as one and three or more. In some embodiments, one or more dummy fin structures are formed on both sides of the fin structures 136 to improve pattern fidelity in the patterning operations.

In some embodiments, a liner 130 can be formed along sidewalls of the fin structure 136, a sidewall of the gate protective layer 126, and sidewalls of the hard mask layers 128a, 128b to protect the fin structure 136 during the subsequent process. In some embodiments, the liner 130 can be formed conformal to the fin structure 136, the gate protective layer 126 and the hard mask layers 128a, 128b. For example, the liner 130 can include an oxide material, such as silicon oxide. The liner 130 may include other suitable dielectric material, such as silicon nitride, silicon oxynitride, low-k dielectric material, other suitable dielectric materials, or combinations thereof.

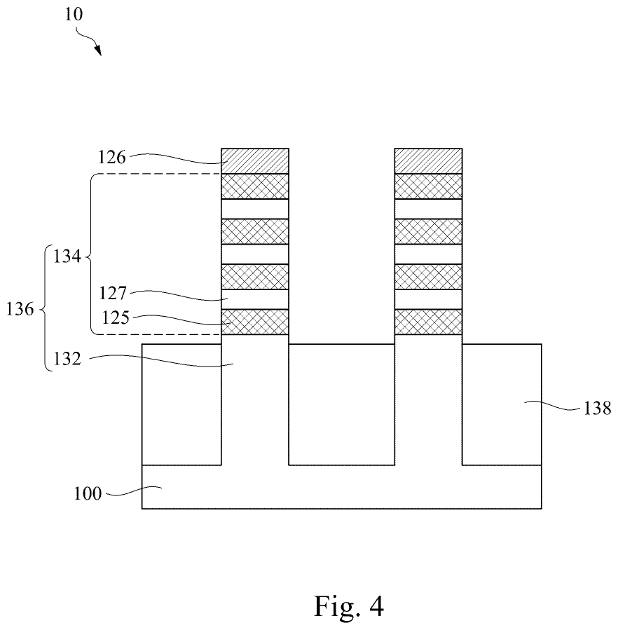

Next, in FIG. 4, Shallow Trench Isolation (STI) regions 138 are formed over the substrate 100 and on opposing sides of the fin structure 136. As an example to form the STI regions 138, an insulation material may be formed over the substrate 100. The insulation material may be an oxide, such as silicon oxide, a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by a FCVD process. An anneal process may be performed after the insulation material is formed.

In an embodiment, the insulation material is formed such that excess insulation material covers the fin structure 136. In some embodiments, a liner (not shown) is firstly formed along surfaces of the substrate 100 and fin structure 136, and a fill material, such as those discussed above is formed over the liner. In some embodiments, the liner is omitted.

Next, a removal process is applied to the insulation material to remove excess insulation material over the fin structure 136. In some embodiments, a planarization process such as a chemical mechanical polish (CMP), an etch back process, combinations thereof, or the like may be utilized. The planarization process exposes the gate protective layer 126 such that top surfaces of the gate protective layer 126 and the insulation material are level after the planarization process is complete. The hard mask layers 128a, 128b can be removed during the planarization process. Next, the insulation material is recessed to form the STI regions 138. The insulation material is recessed such that the nanostructure 134 protrudes from between neighboring STI regions 138. Top portions of the semiconductor fin 132 may also protrude from between neighboring STI regions 138. Further, the top surfaces of the STI regions 138 may have a flat surface as illustrated, a convex surface, a concave surface (such as dishing), or a combination thereof. The top surfaces of the STI regions 138 may be formed flat, convex, and/or concave by an appropriate etch. The STI regions 138 may be recessed using an acceptable etching process, such as one that is selective to the material of the insulation material (e.g., etches the material of the insulation material at a faster rate than the material of the semiconductor fins 132 and the nanostructures 134). For example, a chemical oxide removal with a suitable etchant such as dilute hydrofluoric (dHF) acid may be used. The liner (see FIG. 3) can be partially or entirely consumed during forming the STI regions 138. In some embodiments, in FIG. 4, the liner 130 may be entirely consumed. In some embodiments, after the STI regions 138 are formed, the gate protective layer 126 can remain over the nanostructure 134.

Referring to FIGS. 5A, 5B and 5C, a dummy gate stack 140 is formed over the nanostructure 134 and over the STI region 138. The formation of the dummy gate stack 140 may include forming a dummy gate dielectric over the nanostructure 134 and over the STI region 138 and then forming a dummy gate over the dummy gate dielectric. The dummy gate dielectric may be, for example, silicon oxide, silicon nitride, a combination thereof, or the like, and may be deposited or thermally grown according to acceptable techniques. In an embodiment, a layer of silicon is conformally formed over the nanostructure 134 and over the upper surface of the STI regions 138, and a thermal oxidization process is performed to convert the deposited silicon layer into an oxide layer as the dummy gate dielectric.

The dummy gate layer may be deposited over the dummy gate dielectric and then planarized, such as by a CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other suitable methods. The dummy gate layer may be made of other materials that have a high etching selectivity from the STI region 138. The dummy gate covers respective channel regions of the nanostructures 134. The dummy gate may also have a lengthwise direction substantially perpendicular to the lengthwise direction of the semiconductor fins 132. The dummy gate and the dummy gate dielectric are collectively referred to as dummy gate structure, in some embodiments.

Then, a mask (not shown) can be formed over the dummy gate stack 140 and patterned using acceptable photolithography and etching techniques to form a patterned mask. The pattern of the mask then may be transferred to the dummy gate layer and to the dummy dielectric layer of the dummy gate stack 140.

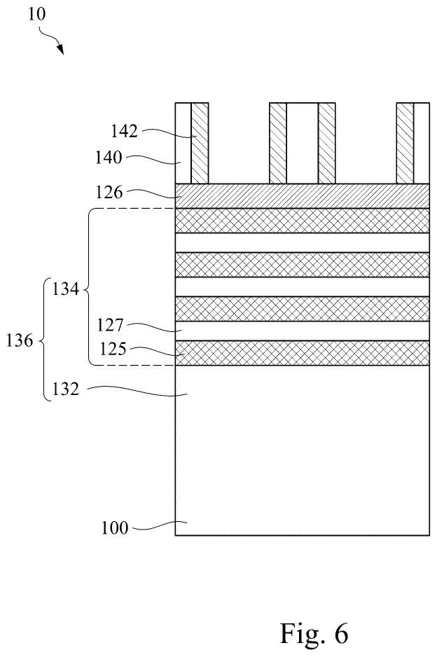

In FIG. 6, gate spacers 142 are formed adjacent to the dummy gate stack 140. For example, the gate spacers 142 are disposed adjacent to (for example, along sidewalls of) the dummy gate stack 140. The gate spacers 142 are formed by any suitable process and include a dielectric material. The dielectric material can include silicon, oxygen, carbon, nitrogen, other suitable material, or combinations thereof (for example, silicon oxide, silicon nitride, silicon oxynitride, or silicon carbide). For example, in the depicted embodiment, a dielectric layer including silicon and nitrogen, such as a silicon nitride layer, can be deposited over the fin structures 136 and the STI regions 138 and subsequently anisotropically etched to form the gate spacers 142. In some implementations, the gate spacers 142 include a multi-layer structure, such as a first dielectric layer that includes silicon nitride and a second dielectric layer that includes silicon oxide. In some implementations, more than one set of spacers, such as seal spacers, offset spacers, sacrificial spacers, dummy spacers, and/or main spacers, are formed adjacent to the dummy gate stack 140. In such implementations, the various sets of spacers can include materials having different etch rates. For example, a first dielectric layer including silicon and oxygen (for example, silicon oxide) can be deposited over the fin structures 136 and the STI regions 138 and subsequently anisotropically etched to form a first spacer set adjacent to the dummy gate stack and on the STI regions 138, and a second dielectric layer including silicon and nitrogen (for example, silicon nitride) can be deposited over the fin structures 136 and the STI regions 138 and subsequently anisotropically etched to form a second spacer set adjacent to the first spacer set.

After the formation of the gate spacers 142, implantation for lightly doped source/drain (LDD) regions (not shown) may be performed. Appropriate type (e.g., p-type or n-type) impurities may be implanted into the exposed nanostructure 134 and/or the semiconductor fin 132. The n-type impurities may be the any suitable n-type impurities, such as phosphorus, arsenic, antimony, or the like, and the p-type impurities may be the any suitable p-type impurities, such as boron, BF₂, indium, or the like. An anneal process may be used to activate the implanted impurities.

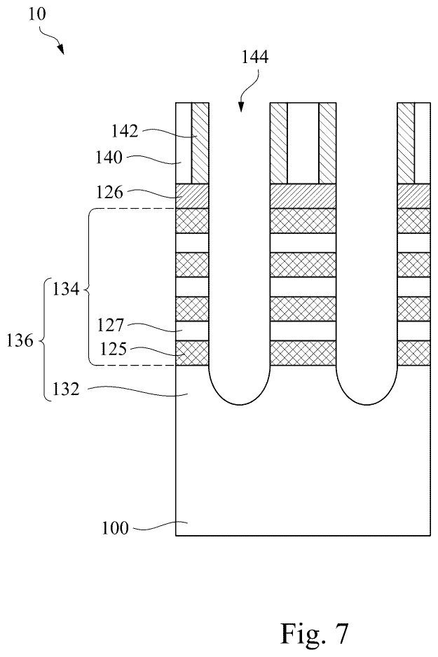

In FIG. 7, source/drain recesses 144 are formed in the fin structures 136 (i.e., the nanostructures 134, and the semiconductor fin 132), in accordance with some embodiments. Epitaxial source/drain regions will be subsequently formed in the source/drain recesses 144. The source/drain recesses 144 may extend through the first nanostructures 125 and the second nanostructures 127, and into the substrate 100. The source/drain recesses 144 may be formed by etching the semiconductor fin 132, the nanostructures 134, and the substrate 100 using anisotropic etching processes, such as RIE, NBE, or the like. The gate spacers 142 mask portions of the semiconductor fin 132, the nanostructures 134, and the substrate 100 during the etching processes used to form the source/drain recesses 144. A single etch process or multiple etch processes may be used to etch each layer of the nanostructures 134 and/or the semiconductor fin 132. Timed etch processes may be used to stop the etching of the source/drain recesses 144 after the source/drain recesses 144 reach a target depth.

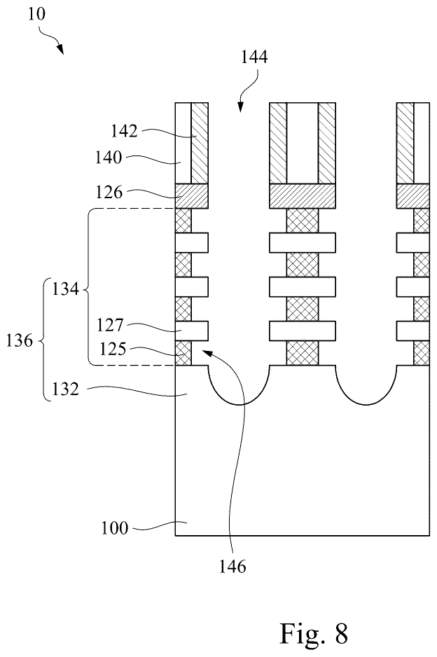

Reference is made to FIG. 8. Portions of sidewalls of the layers of the nanostructure 134 formed of the first semiconductor materials (e.g., the first nanostructures 125) exposed by the source/drain recesses 144 are etched to form sidewall recesses 146 between corresponding second nanostructures 127. Although sidewalls of the first nanostructures 125 in the sidewall recesses 146 are illustrated as being straight in FIG. 8, the sidewalls may be concave or convex. The sidewalls may be etched using isotropic etching processes, such as wet etching or the like. In some embodiments in which the first nanostructures 125 include, e.g., SiGe, and the second nanostructures 127 include, e.g., Si or SiC, a dry etch process with tetramethylammonium hydroxide (TMAH), ammonium hydroxide (NH₄OH), or the like may be used to etch sidewalls of the first nanostructures 125.

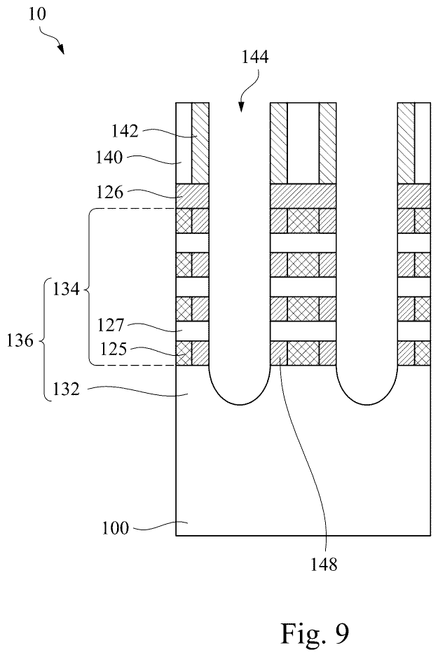

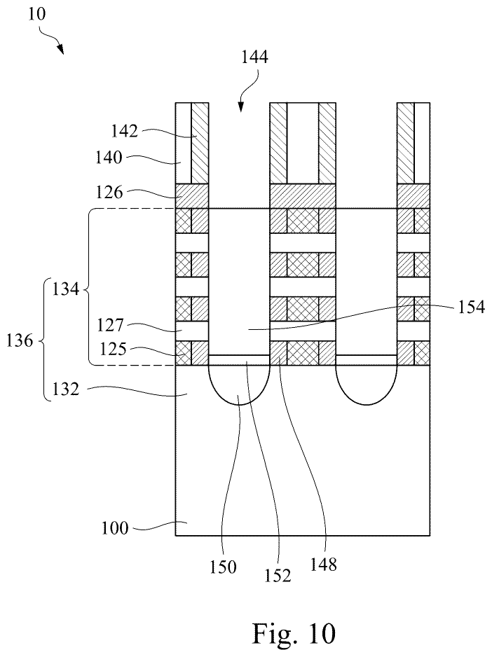

An inner spacer layer is deposited over the fin structures 136, the STI region 138, the dummy gate stack 140 and the source/drain recesses 144. The inner spacer layer is formed in the sidewall recess 146. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the inner spacers 148, as shown in FIG. 9. The inner spacer layer may be etched by an anisotropic etching process, such as RIE, NBE, or the like. The inner spacers 148 may be used to prevent damage to subsequently formed source/drain regions (such as the epitaxial source/drain regions, discussed below with respect to FIG. 10) by subsequent etching processes, such as etching processes used to form gate structures.

The inner spacers 148 act as isolation features between subsequently formed epitaxial source/drain regions and gate structure. As will be discussed in greater detail below, epitaxial source/drain regions will be formed in the source/drain recesses 144, and the first nanostructures 125 will be replaced with corresponding gate structures.

Although outer sidewalls of the inner spacers 148 are illustrated as being flush with sidewalls of the second nanostructures 127, the outer sidewalls of the inner spacers 148 may extend beyond or be recessed from sidewalls of the second nanostructures 127. Moreover, although the outer sidewalls of the inner spacers 148 are illustrated as being straight in FIG. 9, the outer sidewalls of the inner spacers 148 may be concave or convex.

Reference is made to FIG. 10. In some embodiments, a semiconductor layer 150 is formed in a bottom of the source/drain recesses 144. The semiconductor layer 150 may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In some embodiments, a dielectric layer 152 and epitaxial source/drain regions 154 may then be formed over the semiconductor layer 150 in the source/drain recesses 144. The dielectric layer 152 is made of a low-k (dielectric constant lower than the dielectric constant of SiO₂) material in some embodiments. The low-k material includes SiOC, SiOCN, organic material or porous material, or any other suitable material. In other embodiments, the dielectric layer 152 is made of silicon oxide and/or silicon nitride, or any other suitable dielectric material. A bottom of the epitaxial source/drain regions 154 is separated from the fin substrate 100 by the dielectric layer 152 and the semiconductor layer 150, suppressing a leakage current from the epitaxial source/drain regions 154 to the substrate 100.

Epitaxial source/drain regions 154 are formed in the source/drain recesses 144. In some embodiments, the epitaxial source/drain regions 154 may exert stress on the second nanostructures 127, thereby improving device performance. As illustrated in FIG. 10, the epitaxial source/drain regions 154 are formed in the source/drain recesses 144 such that each dummy gate stack 140 is disposed between respective neighboring pairs of the epitaxial source/drain regions 154. In some embodiments, the inner spacers 148 are used to separate the epitaxial source/drain regions 154 from the dummy gate stacks 140 and are used to separate the epitaxial source/drain regions 154 from the first nanostructures 125 by an appropriate lateral distance so that the epitaxial source/drain regions 154 do not short out with subsequently formed gates of the resulting NSFET device.

In some embodiments, the epitaxial source/drain regions 154 may include any acceptable material appropriate for n-type NSFET device. For example, if the second nanostructures 127 are silicon, the epitaxial source/drain regions 154 may include materials exerting a tensile strain on the second nanostructures 127, such as silicon carbide, phosphorous doped silicon carbide, silicon phosphide, or the like.

The epitaxial source/drain regions 154 may be implanted with dopants to form source/drain regions, followed by an anneal. The n-type and/or p-type impurities for source/drain regions may be any of the impurities previously discussed. In some embodiments, the epitaxial source/drain regions 154 may be in situ doped during growth.

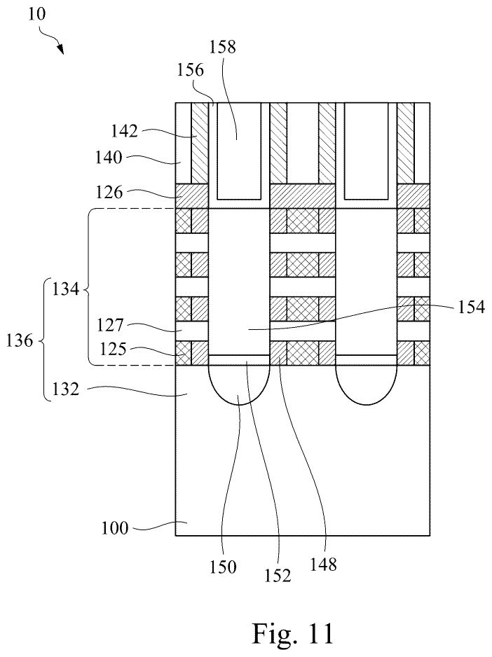

In FIG. 11, a first interlayer dielectric (ILD) layer 158 is deposited over the structure illustrated in FIG. 10. The first ILD layer 158 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a first contact etch stop layer (CESL) 156 is disposed between the first ILD layer 158, and the epitaxial source/drain regions 154, the dummy gate stack 140, and the gate protective layer 126. The first CESL 156 may include a dielectric material, such as, silicon nitride, silicon oxide, silicon oxynitride, or the like, having a different etch rate than the material of the overlying first ILD layer 158.

A planarization process, such as a CMP, may be performed to level the top surface of the first ILD layer 158 with the top surfaces of the dummy gate stacks 140 and the gate spacers 142. After the planarization process, top surfaces of the dummy gate stacks 140, the gate spacers 142, the first CESL 156 and the first ILD layer 158 are level within process variations. Accordingly, the top surfaces of the dummy gate stacks 140 are exposed through the first ILD layer 158.

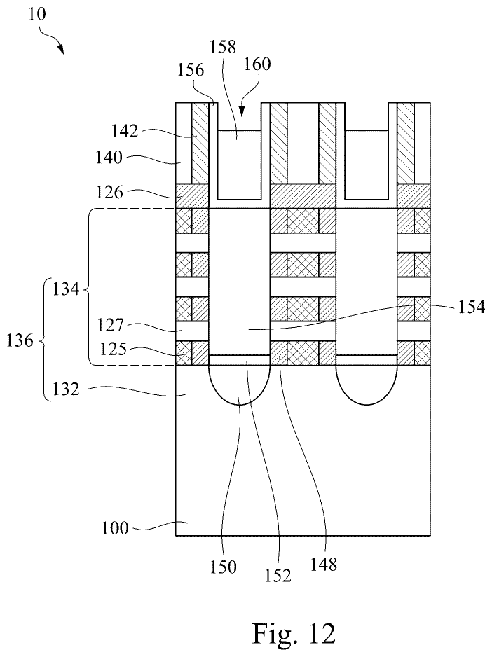

Reference is made to FIG. 12. An upper portion of the first ILD layer 158 is removed using an etching back process to form a recess 160. In the etching back process, the material of the first ILD layer 158 has a high etch selectivity while compared with the materials of the dummy gate stacks 140, the first CESL 156 and the gate spacer 142. The etching process may be a dry etching process, such as a remote plasma etching process. Alternatively, the etching process may be a wet etching process using a chemical etchant that has a high selectivity to the material of the first ILD layer 158 while compared with the materials of the dummy gate stacks 40, the first CESL 156 and the gate spacer 142. The chemical etchant is for example hydrofluoric acid (HF).

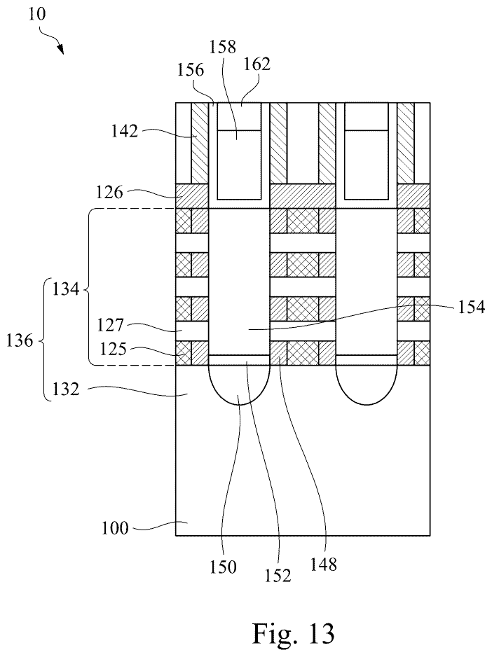

In FIG. 13, a dielectric cap 162 can be formed in a remaining portion of the recess 160 over the first ILD layer 158. The material of the dielectric cap 162 may include metal oxide, silicon oxycarbide (SiOC), silicon carbon nitride (SiCN), silicon nitride (SiN) or silicon oxycarbon nitride (SiOCN), and is selected based on the material used in the gate spacers 142. The dielectric cap 162 may be formed by depositing the material layer of the dielectric cap and then using a planarization process, for example CMP process, to remove excess portions of the deposited material layer over the dummy gate stacks 140, the gate spacers 142 and the first CESL 156. Thereafter, the top surface of the dielectric cap 162 is coplanar with the top surfaces of the dummy gate stacks 140, the gate spacers 142 and the first CESL 156.

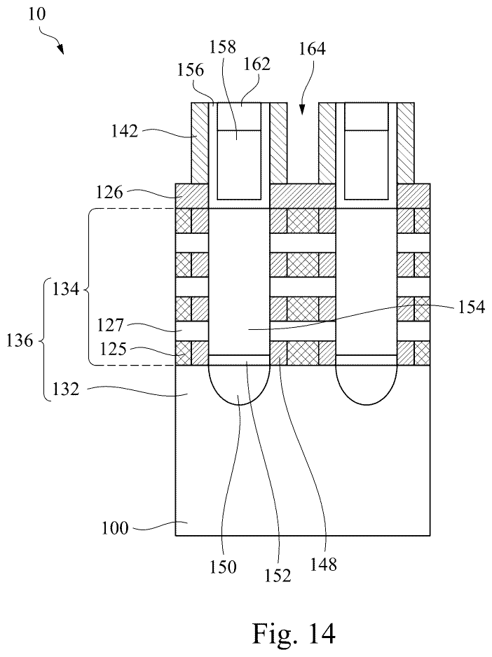

In FIG. 14, the dummy gate stacks 140 are removed in one or more etching steps, so that gate trenches 164 are formed between corresponding gate spacers 142. In some embodiments, the dummy gate stacks 140 are removed by an anisotropic dry etch process. For example, the etching process may include a dry etch process using reaction gas(es) that selectively etch the dummy gate stacks 140 at a faster rate than the first ILD layer 158 or the gate spacers 142. After the dummy gate stacks 140 are removed, the gate protective layer 126 is exposed to the gate trenches 164.

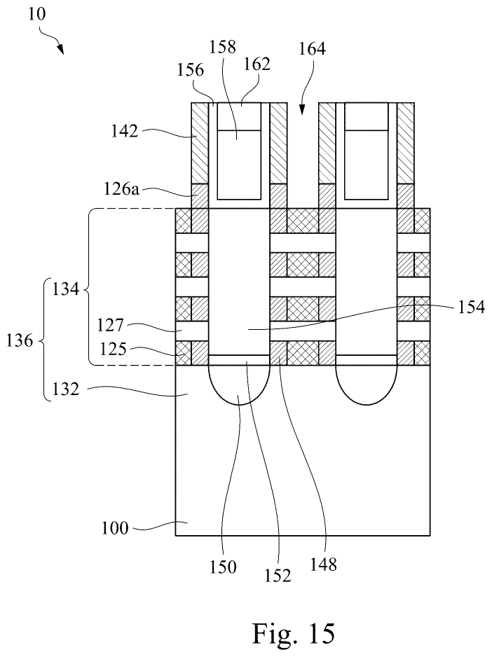

In FIG. 15, a first portion of the gate protective layer 126 over the nanostructures 134 exposed by the gate trenches 164 is etched in one or more etching steps, leaving a second portion of the gate protective layer 126 under the gate spacers 142. The gate trenches 164 can be deepened. Each gate trench 164 exposes and/or overlies portions of nanostructures 134, which act as channel regions in subsequently completed GAA-FETs. The nanostructures 134 which act as the channel regions are disposed between neighboring pairs of the epitaxial source/drain regions 154. In some embodiments, the gate protective layer 126 is etched by an anisotropic dry etch process. For example, the etching process may include a dry etch process using reaction gas(es) that selectively etch the gate protective layer 126 at a faster rate than the dielectric cap 162, the first CESL 156 and the gate spacers 142. Since the gate protective layer 126 can be etched prior to formation of a subsequently formed metal gate stack, the deepened gate trench 164 is beneficial for increasing a thickness of the subsequently formed fill metal of the metal gate stack. The gate protective layer 126 can have separated protective structures 126a remaining between the gate spacers 142 and the inner spacers 148 along the vertical direction (y-direction). The separated gate spacers can be respectively below the gate spacers 142. In some embodiments, the protective structures 126a can have a sidewall substantially aligned with a sidewall of the gate spacer 142.

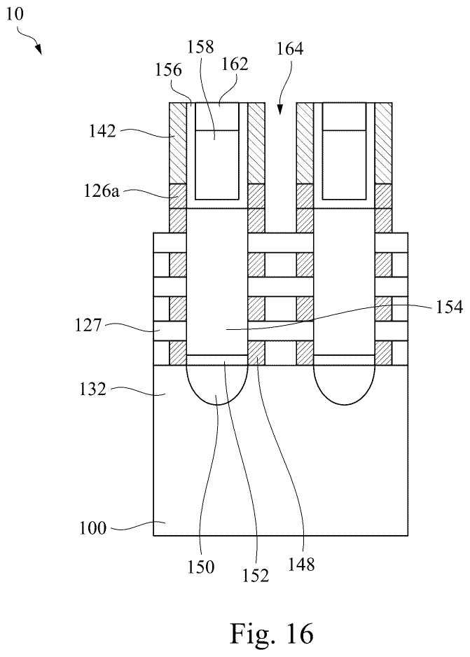

In FIG. 16, the first nanostructures 125 in the gate trenches 164 are removed by an isotropic etching process such as wet etching or the like using etchants which are selective to the materials of the first nanostructures 125. Stated differently, the first nanostructures 125 are removed by using a selective etching process that etches the first nanostructures 125 at a faster etch rate than it etches the second nanostructures 127, thus forming spaces between the second nanostructures 127 (also referred to as sheet-sheet spaces if the nanostructures 134 are nanosheets). This step can be referred to as a channel release process. At this interim processing step, the spaces between second nanostructures 127 may be filled with ambient environment conditions (e.g., air, nitrogen, etc). In some embodiments, the second nanostructures 127 can be referred to as nanosheets, nanowires, nanoslabs, nanorings having nano-scale size (e.g., a few nanometers), depending on their geometry. For example, in some embodiments the second nanostructures 127 may be trimmed to have a substantial rounded shape (i.e., cylindrical) due to the selective etching process for completely removing the first nanostructures 125. In that case, the resultant second nanostructures 127 can be called nanowires.

In embodiments in which the first nanostructures 125 include, e.g., SiGe, and the second nanostructures 127 include, e.g., Si or SiC, tetramethylammonium hydroxide (TMAH), ammonium hydroxide (NH₄OH) or the like may be used to remove the first nanostructures 125. In some embodiments, both the channel release step and the previous step of laterally recessing first nanostructures 125 (i.e., the step as illustrated in FIG. 8) use a selective etching process that etches first nanostructures 125 (e.g., SiGe) at a faster etch rate than etching second nanostructures 127 (e.g., Si), and therefore these two steps may use the same etchant chemistry in some embodiments. In this case, the etching time/duration of channel release step is longer than the etching time/duration of the previous step of laterally recessing first nanostructures 125, so as to completely remove the sacrificial nanostructures 125.

FIG. 17B is an enlarged view R1 in FIG. 17A in accordance with some embodiments. In FIGS. 17A-17C, an interfacial layer 165 and a gate dielectric layer 166 are deposited conformally in the gate trenches 164. The interfacial layer 165 may include an oxide-containing material such as silicon oxide or silicon oxynitride and may be formed by chemical oxidation using an oxidizing agent (e.g., hydrogen peroxide (H₂O₂), ozone (O₃)), plasma enhanced atomic layer deposition, thermal oxidation, ALD, CVD, and/or other suitable methods. In some embodiments, a cleaning process, such as an HF-last pre-gate cleaning process (for example, using a hydrofluoric (HF) acid solution), may be performed before the interfacial layer 165 is formed in the gate trenches 164. The gate dielectric layer 166 wraps around the second nanostructures 127. In some embodiments, the gate dielectric layer 166 includes high-k dielectric material having a high dielectric constant, for example, greater than that of thermal silicon oxide (˜3.9). The high-k dielectric material may include hafnium oxide (HfO₂), zirconium oxide (ZrO₂), lanthanum oxide (La₂O₃), aluminum oxide (Al₂O₃), titanium oxide (TiO₂), yttrium oxide, strontium titanate, hafnium oxynitride (HfOₓN_{y}), other suitable metal-oxides, or combinations thereof. The gate dielectric layer 166 may be formed by ALD, chemical vapor deposition (CVD), physical vapor deposition (PVD), remote plasma CVD (RPCVD), plasma enhanced CVD (PECVD), metal organic CVD (MOCVD), sputtering, other suitable processes, or combinations thereof.

One or more work function metal layers 168 are deposited on the gate dielectric layer 166. In some embodiments where the NSFET device 10 is used as an n-type FET device, the work function metal layers 168 can be n-type work function metal layers such as titanium aluminide (TiAlₓ), titanium aluminium carbide (TiAlC) with a thickness 168t, such as about 0.5 nm to about 3 nm. In some embodiments where the NSFET device 10 is used as a p-type FET device, the work function metal layers 168 can be p-type work function metal layers such as titanium nitride (TiN) with the thickness 168t, such as about 0.5 nm to about 4 nm. In some embodiments, a fill metal 170 can fill into the remaining portion of the gate trench 164 followed by a CMP process to remove excessive portions of the fill metal 170, the work function metal layers 168 and the gate dielectric layer 166. In some embodiments, the fill metal 170 may include TiN. In some other embodiments, the fill metal 170 may include copper (Cu), aluminum (Al), tungsten (W), copper, copper magnesium (CuMn), copper aluminum (CuAl) or copper silicon (CuSi), and/or other suitable conductive material. The fill material may be formed by PVD, CVD, metal-organic chemical vapor deposition (MOCVD) or other suitable methods. The work function metal layers 168 can be covered by the fill metal 170. In some embodiments where the NSFET device 10 is used as either a p-type FET device or an n-type FET device, the fill metal 170 can be TiN with a thickness 170t in a range from about 0.5 nm to about 4 nm.

FIG. 18B is an enlarged view R2 of FIG. 18A. Reference is made to FIGS. 18A, 18B and 18C. In FIG. 18C, in some embodiments, a gate isolation structure is formed to separate portions of the metal gate stack 172. In one embodiment, the gate isolation structure is a cut metal gate (CMG) gate isolation 188. Formation of the CMG isolation structure 188 may include forming a cut metal gate trench extending into the STI regions 138 to ensure that the two portions of the metal gate stack 172 are isolated from each other. A dielectric material then fills into the cut metal gate trench followed by preforming a planarization process such as CMP to level a top surface of the CMG isolation structure 188, a top surface of the metal gate stack 172, a top surface of the protective structures 126a, the first ILD layer 158 and the first CESL 156. The fill metal 170, the work function metal layers 168, and the corresponding gate dielectric layer 166 may be collectively referred to as a metal gate stack 172. The CMG gate isolation 188 will contact gate dielectric layer 166, work function metal layers 168 and fill metal 170. In some embodiments, the fill metal 170 of the metal gate stack 172 can have a thickness t1 in the vertical direction. The planarization process exposes the protective structures 126a of the gate protective layer 126 such that top surfaces of the protective structures 126a the gate protective layer 126, the first ILD layer 158, the first CESL 156, and the metal gate stack 172 are level with one another after the planarization process is complete. The dielectric cap 162 and the gate spacers 142 can be removed during the planarization process.

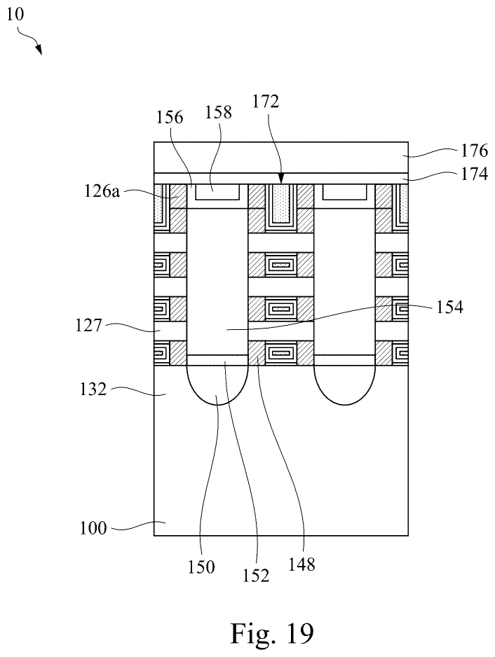

Reference is made to FIG. 19. A second contact etch stop layer (CESL) 174 can be formed over the metal gate stack 172, the protective structures 126a of the gate protective layer 126, the first CESL 156 and the first ILD layer 158. The second ILD layer 176 and the second CESL 174 will protect the metal gate stack 172 during source/drain contact etching. In some embodiments, the second CESL 174 and the second ILD layer 176 may be similar to the first CESL 156 and the first ILD layer 158 in terms of composition and formation method thereof, and thus the description thereof is omitted herein.

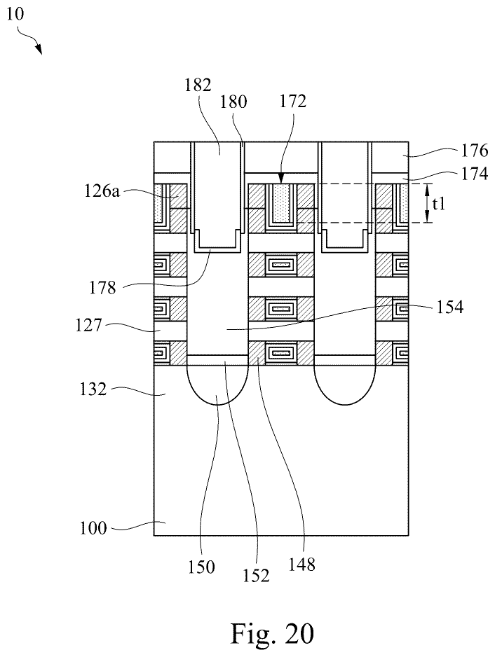

Next, contact holes can be formed through the second ILD layer 176, the second CESL 174, the first ILD layer 158 and the first CESL 156 to expose the epitaxial source/drain regions 154. Formation of the contact holes may include patterning the second ILD layer 176, the second CESL 174, the first ILD layer 158 and the first CESL 156 by a photolithography process. Afterwards, in some embodiments, a metal layer (not shown) may be deposited over the epitaxial source/drain regions 154 by, for example, PVD, CVD, metal-organic chemical vapor deposition (MOCVD), sputtering, or other suitable methods. The metal layer can be a material such as Co, Ti, W, Ni, Mo, Ta, or Pt, alloy thereof, or the like. Thereafter, an anneal step is performed to initiate a reaction between the metal layer and the epitaxial source/drain regions 154 to form a metal silicide layer 178 as shown in FIG. 20. Un-reacted metal layer can then be removed by using a chemical that attacks un-reacted metal layer, but not the metal silicide layer 178.

A barrier layer 180 is formed on sidewalls of the contact hole. In an embodiment, the barrier layer 180 is formed by depositing a material layer over the second ILD layer 176, and on the sidewalls of the contact hole and on the metal silicide layer 178. Then an anisotropic etching process is performed to remove portions of the material layer over the second ILD layer 176 and over the metal silicide layer 178, leaving the remaining portions of the material layer on the sidewalls of the contact hole as the barrier layer. In some embodiments, the barrier layer can include TiN, Ti, Ni, Co, or a combination thereof and can be deposited by ALD, CVD, or other suitable deposition methods.

One or more conductive materials fill into the contact hole followed by a CMP process to remove excessive portions of the conductive materials, forming gate contacts 182. The conductive materials may include copper (Cu), aluminum (Al), tungsten (W), copper, copper magnesium (CuMn), copper aluminum (CuAl) or copper silicon (CuSi), and/or other suitable conductive material. The conductive materials may be formed by PVD, CVD, metal-organic chemical vapor deposition (MOCVD), or plating. The fill metal 170 is thick enough such that the margin for etching the second ILD layer 176 and the second CESL 174 without etching too much fill metal 170 of the metal gate stack 172 can be increased.

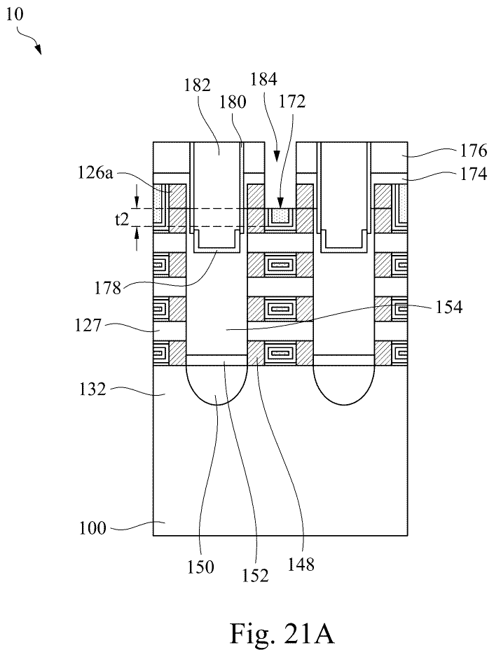

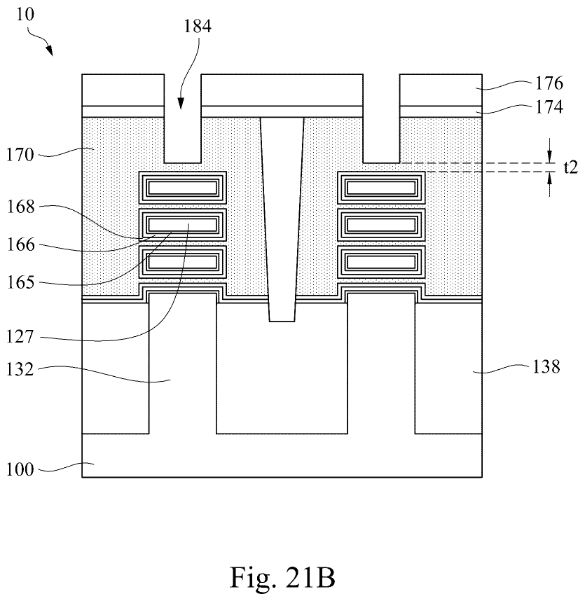

Reference is made to FIGS. 21A and 21B. Next, contact holes 184 are formed through the second ILD layer 176, the second CESL 174 and the metal gate stack 172 to expose the metal gate stack 172. Formation of the contact holes 184 may include patterning the second ILD layer 176, the second CESL 174 and the metal gate stack 172 by a photolithography process, etching the second ILD layer 176, the second CESL 174 and the metal gate stack 172 (for example, by using a dry etching, wet etching, and/or plasma etching process) to remove portions of the second ILD layer 176, the second CESL 174 and the metal gate stack 172. As discussed previously with regard to FIG. 15, the gate protective layer 126 can be etched prior to formation of the metal gate stack 172. Therefore, an additional etching process to break through the gate protective layer 126 and the gate dielectric layer 166 to expose the metal gate stack 172 can be omitted. In some embodiments, the fill metal 170 of the metal gate stack 172 can include a thickness t2 less than the thickness t1 (see FIG. 20). That is, the fill metal 170 can remain after forming the contact holes 184. Unwanted entirely removal of the fill metal 170 and oxidation of the work function metal layer 168 which may cause the high contact resistance between a subsequently formed gate contact and the metal gate stack 172 can be prevented.

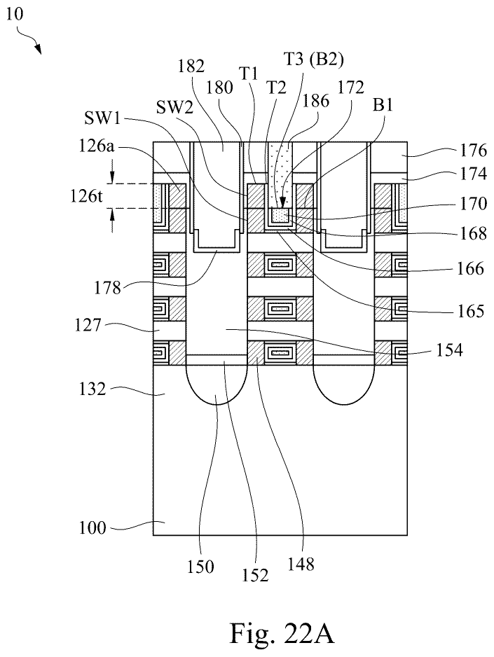

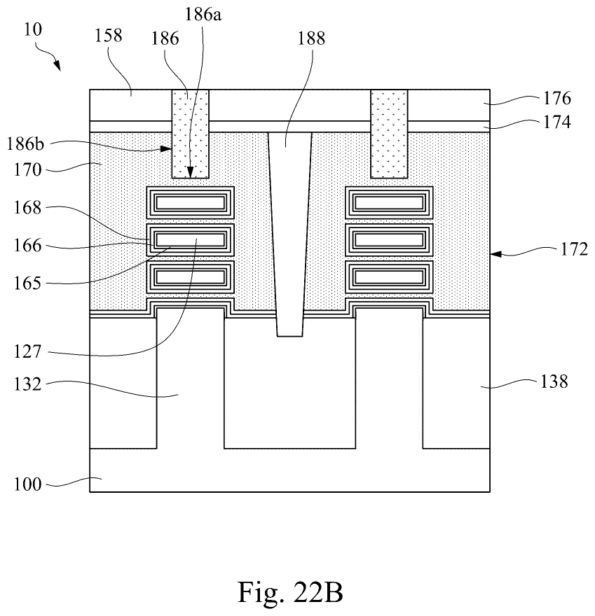

Reference is made to FIGS. 22A and 22B. One or more conductive materials fill into the contact holes 184 followed by a CMP process to remove excessive portions of the conductive materials, forming gate contacts 186. The fill metal 170 can have a top surface interfacing the gate contact 186. The gate contact 186 can extend through a region between the protective structures 126a into the fill metal 170 of the metal gate stack 172, and the gate contact 186 can have a bottom surface in contact with the fill metal 170. In FIG. 22A, the work function metal layer 168 can have a U-shape cross-section, and the gate contact 186 can have opposite sidewalls in contact with the gate dielectric layer 166. The inner spacer 148 over a topmost one of the nanostructures 127 has an outer sidewall SW1 substantially aligned with a sidewall SW2 of one of the protective structures 126a of the gate protective layer 126. The gate dielectric layer 166 can have a top surface T2 substantially level with a top surface T1 of the one of the protective structures 126a of the gate protective layer 126. The fill metal 170 can have a top surface T3 substantially level with a bottom surface B1 of one of the protective structures 126a of the gate protective layer 126. The gate dielectric layer 166 can be laterally between the gate contact 186 and the protective structures 126a of the gate protective layer. The gate contact 186 can have a bottom surface B2 substantially level with the bottom surface B1 of the protective structures 126a the gate protective layer 126. The conductive materials may include copper (Cu), aluminum (Al), tungsten (W), copper, copper magnesium (CuMn), copper aluminum (CuAl) or copper silicon (CuSi), and/or other suitable conductive material. The conductive materials may be formed by PVD, CVD, metal-organic chemical vapor deposition (MOCVD), or plating. The protective structures 126a can be on opposite sides of the gate contact 186. The protective structures 126a can have the thickness 126t along the vertical direction. The protective structures 126a is absent under the gate contacts 186 in the vertical direction. In some embodiments, the gate contacts 186 can be in direct contact with the fill metal 170 which is beneficial for reducing the contact resistance. For example, the gate contacts 186 can be in direct contact with a top surface of the fill metal 170 and a top surface of the work function metal layer 168. In some embodiments, the gate dielectric layer 166 can be in contact with opposite lower sidewalls of the gate contact 186. In cross-sectional view in FIG. 22B, the gate contacts 186 can have a lower portion (e.g., a bottom surface 186a and opposite lower sidewalls 186b) surrounded by the fill metal 170. The gate contacts 186 can be in direct contact with the fill metal 170 instead of the work function metal layer 168 in cases where the NSFET device 10 is NFET or PFET.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that with the gate protective layer removed and the metal gate stack having increased thickness, the margin for gate contact etching process without excessively etching the fill metal of the metal gate stack is improved. Another advantage is that the gate contact can interface with the fill material, thereby reducing contact resistance.

In some embodiments, a method of forming a semiconductor device comprises the following steps. A multi-layer stack is formed over a substrate, wherein the multi-layer stack comprises alternately stacked first semiconductor layers and second semiconductor layers. A dielectric protective layer is formed over the multi-layer stack. Gate spacers are formed over the dielectric protective layer. A first portion of the dielectric protective layer is removed from a top surface of the multi-layer stack, while leaving second portions of the dielectric protective layer under the gate spacer. The first semiconductor layers are replaced with a metal gate stack. Gate contact is formed over the metal gate stack. In some embodiments, removing the first portion of the dielectric protective layer is performed prior to replacing the first semiconductor layers with the metal gate stack. In some embodiments, the metal gate stack comprises a gate dielectric layer surrounding each of the second semiconductor layers, a work function metal layer over the gate dielectric layer and a fill metal over the work function metal layer, wherein the fill metal has a top surface interfacing the gate contact. In some embodiments the fill metal comprises TiN. In some embodiments, the work function metal layer comprises TiAlC, TiAlₓ or a combination thereof. In some embodiments, the fill metal and the work function metal layer comprise TiN. In some embodiments, the dielectric protective layer comprises SiCN, SiOCN, or a combination thereof. In some embodiments, the work function metal layer has a U-shape cross-section.

In some embodiments, a method of forming semiconductor device comprises the following steps. A gate protective material is formed over a semiconductor structure. The gate protective material and the semiconductor structure are etched to form a gate protective layer and a fin, respectively. A dummy gate is formed cross the gate protective layer and the fin. Gate spacers are formed on opposite sidewalls of the dummy gate. The dummy gate is removed to form a gate trench between the gate spacers. The gate protective layer is etched to form separated protective structures respectively below the gate spacers. A metal gate is formed across a semiconductor material in the fin. In some embodiments, the metal gate comprises a gate dielectric layer, a work function metal layer over the gate dielectric layer and a fill metal over the work function metal layer, wherein the fill metal has a top surface substantially level with bottom surfaces of the protective structures. In some embodiments, the gate dielectric layer has a top surface substantially level with top surfaces of the protective structures. In some embodiments, forming the metal gate across the fin is performed after etching the gate protective layer.

In some embodiments, a semiconductor device comprises a substrate, nanostructures over the substrate and arranged separately along a vertical direction, a gate structure. The gate structure comprises a gate dielectric layer surrounding each of the nanostructures, a work function metal layer over the gate dielectric layer, a fill metal over the work function metal layer, dielectric protective structures on opposite sides of the gate structure and a gate contact extending through a region between the dielectric protective structures into the fill metal of the gate structure, the gate contact having a bottom surface in contact with the fill metal. In some embodiments, the gate contact has opposite sidewalls in contact with the gate dielectric layer. In some embodiments, the semiconductor device further comprises an inner spacer over a topmost one of the nanostructures, wherein the inner spacer has an outer sidewall substantially aligned with a sidewall of one of the dielectric protective structures. In some embodiments, a lower portion of the gate contact is surrounded by the fill metal. In some embodiments, the gate contact has opposite sidewalls in contact with the fill metal. In some embodiments, the gate dielectric layer separates the gate contact from the dielectric protective structures. In some embodiments, the fill metal is TiN In some embodiments, the bottom surface of the gate contact is substantially level with bottom surfaces of the dielectric protective structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
forming a multi-layer stack over a substrate, wherein the multi-layer stack comprises alternately stacked first semiconductor layers and second semiconductor layers;
forming a dielectric protective layer over the multi-layer stack;
forming gate spacers over the dielectric protective layer;
removing a first portion of the dielectric protective layer from a top surface of the multi-layer stack, while leaving second portions of the dielectric protective layer under the gate spacer;
replacing the first semiconductor layers with a metal gate stack; and
forming a gate contact over the metal gate stack.

2. The method of claim 1, wherein removing the first portion of the dielectric protective layer is performed prior to replacing the first semiconductor layers with the metal gate stack.

3. The method of claim 1, wherein the metal gate stack comprises:
a gate dielectric layer surrounding each of the second semiconductor layers;
a work function metal layer over the gate dielectric layer; and
a fill metal over the work function metal layer, wherein the fill metal has a top surface interfacing the gate contact.

4. The method of claim 3, wherein the fill metal comprises TiN.

5. The method of claim 3, wherein the work function metal layer comprises TiAlC, TiAlₓ or a combination thereof.

6. The method of claim 3, where the fill metal and the work function metal layer comprise TiN.

7. The method of claim 3, wherein the dielectric protective layer comprises SiCN, SiOCN, or a combination thereof.

8. The method of claim 3, wherein the work function metal layer has a U-shape cross-section.

9. A method of forming semiconductor device, comprising:
forming a gate protective material over a semiconductor structure;
etching the gate protective material and the semiconductor structure to form a gate protective layer and a fin, respectively;
forming a dummy gate cross the gate protective layer and the fin;
forming gate spacers on opposite sidewalls of the dummy gate;
removing the dummy gate to form a gate trench between the gate spacers;
etching the gate protective layer to form separated protective structures respectively below the gate spacers; and
forming a metal gate across a semiconductor material in the fin.

10. The method of claim 9, wherein the metal gate comprises:
a gate dielectric layer;
a work function metal layer over the gate dielectric layer; and
a fill metal over the work function metal layer, wherein the fill metal has a top surface substantially level with bottom surfaces of the protective structures.

11. The method of claim 10, wherein the gate dielectric layer has a top surface substantially level with top surfaces of the protective structures.

12. The method of claim 9, wherein forming the metal gate across the fin is performed after etching the gate protective layer.

13. A semiconductor device, comprising:
a substrate;
nanostructures over the substrate and arranged separately along a vertical direction;
a gate structure comprising:
a gate dielectric layer surrounding each of the nanostructures;
a work function metal layer over the gate dielectric layer; and
a fill metal over the work function metal layer;
dielectric protective structures on opposite sides of the gate structure; and
a gate contact extending through a region between the dielectric protective structures into the fill metal of the gate structure, the gate contact having a bottom surface in contact with the fill metal.

14. The semiconductor device of claim 13, wherein the gate contact has opposite sidewalls in contact with the gate dielectric layer.

15. The semiconductor device of claim 13, further comprising:
an inner spacer over a topmost one of the nanostructures, wherein the inner spacer has an outer sidewall substantially aligned with a sidewall of one of the dielectric protective structures.

16. The semiconductor device of claim 13, wherein a lower portion of the gate contact is surrounded by the fill metal.

17. The semiconductor device of claim 13, wherein the gate contact has opposite sidewalls in contact with the fill metal.

18. The semiconductor device of claim 13, wherein the gate dielectric layer separates the gate contact from the dielectric protective structures.

19. The semiconductor device of claim 13, wherein the fill metal is TiN.

20. The semiconductor device of claim 13, wherein the bottom surface of the gate contact is substantially level with bottom surfaces of the dielectric protective structures.
